(19) United States
(12) Patent Application Publication
(10) Pub. No.: US 2026/0037693 A1
(43) Pub. Date: Feb. 5, 2026

(54) MANAGING CONFLICTING BELIEFS USING A DIGITAL TWIN

(71) Applicant: Dell Products L.P., Round Rock, TX (US)

(72) Inventors: OFIR EZRIELEV, Be'er Sheva (IL); HANNA YEHUDA, Acton, MA (US); TSEHSIN JASON LIU, Wellesley, MA (US); YONIT LOPATINSKI, Shomria (IL)

(21) Appl. No.: 18/788,464

(22) Filed: Jul. 30, 2024

(51) Int. Cl. G06F 30/27

(52) U.S. Cl. CPC G06F 30/27

(57) ABSTRACT

Methods and systems for managing conflicting beliefs in the state of a system are disclosed. To manage the conflicting beliefs, differences in beliefs may be resolved. To resolve the differences, the sources of the different beliefs may be ranked with respect to likelihood of being correct in the respective belief. The rankings may be used to select one of the beliefs as being a trustworthy belief in the state of the system. The selected belief may be used to provide desired computer implemented services.

### FIELD

Embodiments disclosed herein relate generally to managing a system. More particularly, embodiments disclosed herein relate to systems and methods to manage conflicts in systems.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components and the components of other devices may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1 shows a block diagram illustrating a system in accordance with an embodiment.

FIGS. 2A-2D show diagrams illustrating data flows in accordance with an embodiment.

FIG. 3 shows a flow diagram illustrating a method of managing conflicting policies in accordance with an embodiment.

FIG. 4 shows a diagram illustrating an example of a new policy obtained by the system in accordance with an embodiment.

FIG. 5 shows a diagram illustrating a data flow in accordance with an embodiment.

FIG. 6 shows a flow diagram illustrating a method of managing conflicting data in accordance with an embodiment.

FIG. 7 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods and systems for managing conflicting policies and conflicting beliefs regarding the state of a system. Policies may include action sets keyed to predicted states, and the action sets may be usable to update operation of one or more data processing systems that are likely to be impacted by the predicted states. At least a portion of the predicted states may be interpreted as an event (e.g., a sandstorm, wind, a temperature increase). The occurrence of the predicted state may affect the availability of resources used to provide computer-implemented services (e.g., data processing systems, hardware and/or software components of the data processing systems), which may result in undesired outcomes. Thus, the action sets may be performed in order to hedge against a risk of undesired outcomes from the occurrence of the predicted states.

To obtain the predicted states, an inference model (e.g., digital twin) may be used to generate predictions regarding whether a state will occur at a future point in time. Based on the predictions, policies (e.g., from a policy library) may be invoked based on a type of the predicted state so that resources may be distributed and/or otherwise made available to provide the computer-implemented services.

However, more than one policy from the policy library may be invoked based on the type of predicted state (e.g., due to undetected redundancies, due to errors), and the invoked policies may include conflicting action sets. As a result of the conflicting action sets, a policy may be unable to be implemented and/or a policy may be implemented which prevents the data processing systems from providing the computer-implemented services (e.g., by following a command to operate under conditions which results in damage to the data processing systems). Thus, the presence of conflicting policies in the policy library may result in provision of computer-implemented services which are of a reduced quality, interrupted, and/or delayed.

To improve a likelihood that resources will be available to provide the computer-implemented services, conflicting policies from the policy library may be identified. To identify conflicting policies, a digital twin may be used to generate simulated conditions (e.g., simulated operation of the data processing systems) based on a set of initial conditions. The simulated conditions may be used to obtain a simulated predicted state. Based on the simulated predicted state, it may be determined whether multiple policies from the policy library are invoked.

If multiple policies are invoked, action sets corresponding to each of the policies may be compared to determine whether any actions of the action sets conflict (e.g., are mutually exclusive, reduce a likelihood of meeting operational goals for the one or more data processing systems). If conflicting actions are identified, a new policy may be obtained which may include an action set that overrides the action sets of the conflicting policies.

To identify which policies are invoked, conflicting beliefs regarding the state of the system may be resolved prior to use in simulating the future operation of the system. Conflicts in belief may arise due to, for example, malfunction of different portions of a system, inaccurate assumptions, and/or other reasons.

To resolve the conflicts in belief regarding the state of the system, an existing simulation of the system may be used to rank different system components in their likelihood to provide accurate information. The rankings may be used to select sources of data for use in simulations, and exclude other sources from use in the simulations.

Thus, embodiments disclosed herein may address, among other technical problems, the technical challenge of identifying and resolving both policy conflicts of a policy library and belief conflicts. By resolving the conflicts and beliefs, the system may be more likely to provide desired computer implemented services.

In an embodiment, a method for managing data processing systems is provided. The method may include obtaining, from a first data source, first data indicating a first value for a quantity used in a digital twin model for the data processing systems; obtaining, from a second data source, second data indicating a second value for the quantity used in the digital twin model for the data processing systems; making an determination regarding whether a difference between the first value and the second value meet criteria; in a first instance of the determination where the difference meets the criteria: obtaining a first risk score for the first data source; obtaining a second risk score for the second data source; selecting, based on the first risk score and the second risk score, either the first value or the second value as a trustworthy value; simulating, using the digital twin model and the trustworthy value, at least one potential future state of the data processing systems; and providing computer implemented services using the data processing systems and the at least one potential future state.

The first risk score may be based on simulated operation of the first data source, and the second risk score may be based on simulated operation of the second data source.

A magnitude of the first risk score may be based on, at least in part, a likelihood of malfunction of the first data source when the first data is obtained, the likelihood of malfunction may be based on the simulated operation of the first data source.

The magnitude of the first risk score may be further based on, at least in part, an event predicted by simulated operation of other entities that impact the simulated operation of the first data source but that are not taking into account when the first data is obtained.

The magnitude of the first risk score may be further based on, at least in part, a second likelihood of malfunction of the first data source when the first data is obtained, the second likelihood of malfunction may be based on a second simulated operation of the first data source.

The second simulated operation of the first data source may include a set of values selected to represent a stochastic element, the simulated operation of the first data source may include a second set of values selected to represent the stochastic element, and the first set of values may be different from the second set of values.

The simulated operation of the first data source may be simulated using the digital twin model.

The first risk score may be based on a function that ingests information obtained from at least one simulation of operation of the data processing systems using the digital twin model.

The information may include indicators of malfunction (e.g., temperature exceeding limits, power consumption too low/high, unexpected data ingest/output, etc.) of the first data source.

The first risk score and the second risk score may reflect levels of trust in the first data source and the second data source operating in accordance with predefined expectations (e.g., nominal operation, provide measurements within prescribed levels of accuracy, etc.).

The first data source may be a first sensor, the second data source may be a second sensor, and the first value and the second value may be based on measurements, by the first sensor and the second sensor, respectively, that are consistent when the measurements are performed correctly (e.g., within expectations of accuracy for the data sources).

Providing the computer implemented services may include identifying, based at least in part on the at least one potential future state, a policy applicable to the data processing systems; updating, based on the policy, operation of the data processing systems to obtain updated data processing systems; and using the updated data processing systems to provide the computer implemented services.

In an embodiment, a non-transitory media is provided that may include instructions that when executed by a processor cause the computer-implemented method to be performed.

In an embodiment, a data processing system is provided that may include the non-transitory media and a processor, and may perform the computer-implemented method when the computer instructions are executed by the processor.

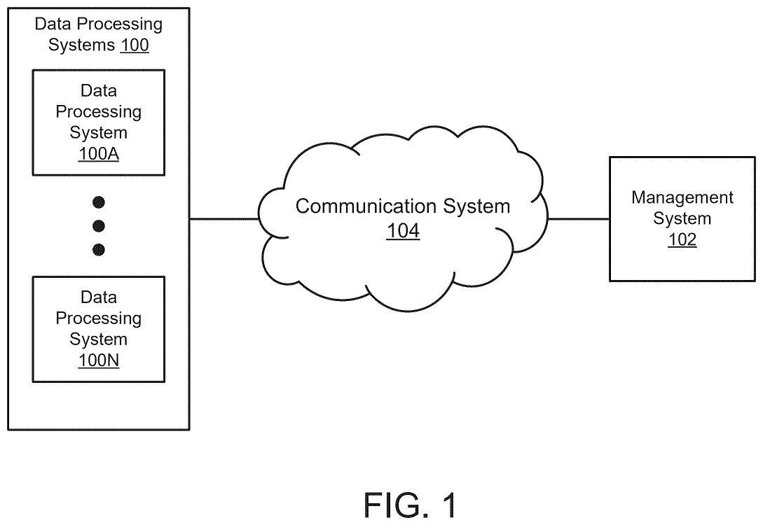

Turning to FIG. 1, a block diagram illustrating a system in accordance with an embodiment is shown. The system shown in FIG. 1 may provide for management of data processing systems that may provide, at least in part, computer-implemented services. The computer-implemented services may include any type and quantity of services including, for example, data services (e.g., data storage, generation, access and/or control services), communication services (e.g., instant messaging services, video-conferencing services), and/or any other type of service that may be implemented with a computing device. The computer-implemented services may be provided by, for example, data processing systems 100, management system 102, and/or any other type of devices (not shown in FIG. 1). Other types of computer-implemented services may be provided by the system shown in FIG. 1 without departing from embodiments disclosed herein.

The system may include any number and/or type of data processing systems 100 (e.g., 100A-100N). Data processing systems 100 may include any number of hardware components (e.g., processors, memory modules, storage devices, communications devices). The hardware components may support execution of any number and type of applications (e.g., software components). Changes in available functionalities of the hardware and/or software components may provide for various types of different computer-implemented services to be provided over time.

To provide the computer-implemented services, a predetermined quantity of hardware and/or software resources may be used. For example, data processing systems 100 may include robotic entities such as unmanned aerial vehicles (e.g., drones) used to provide agriculture management services. To provide the agriculture management services, the drones may be deployed to a geographic location (e.g., a field used to produce crops) to spray portions of the field with pesticide. To ensure a desired coverage of the field with pesticide, a certain number of drones may be deployed.

The provision of the computer-implemented services by data processing systems 100 may be managed by, for example, management system 102. Management system 102 may host at least one inference model used to generate predictions based on input data regarding occurrences of future states which may impact the provision of the computer-implemented services (e.g., performance data of the data processing systems, sensor data collected by the data processing systems, observational weather data collected by doppler radar, radiosondes, weather satellites, buoys, etc.).

Returning to the above example, management system 102 may host an inference model used to generate predictions regarding occurrences of weather events which may impact the ability of the drones to provide the agriculture management services. For example, the inference model may generate predictions regarding a likelihood that an impending thunderstorm may damage at least a portion of the drones, resulting in undesired outcomes, such as an inability of the drones to spray the pesticide.

Based on the predictions generated by the inference model, implementation of a policy (e.g., from a policy library) may invoked based on a type of the predicted state to hedge against a risk of an undesired outcome from the occurrence of the predicted state. Continuing with the above example, a policy may be invoked which includes a command (e.g., based on an action set included in the policy) for the drones to spray the pesticide after the thunderstorm passes to prevent damage to the drones.

However, more than one policy from the policy library may be invoked based on at least the type of state, and the invoked policies may include conflicting commands (e.g., due to undetected redundancies in the policy library, due to errors). For example, a policy may be invoked which includes a command for the drones to spray the pesticide after the thunderstorm passes, and another policy may be invoked which includes a command for the drones to spray the pesticide during the thunderstorm. As a result of the conflict, a policy may be unable to be implemented and/or a policy may be implemented which negatively impacts an ability of the drones to provide the agriculture management services (e.g., by following a command to operate under conditions which results in damage to the drones). Thus, the presence of conflicting policies in the policy library may result in computer-implemented services which are of a reduced quality, interrupted, and/or delayed.

Further, any of the sources of data used in prediction of future states of the data processing systems may be subject to error. For example, data sources such as sensors may malfunction. Accordingly, different data sources may provide conflicting information for a same quantity, phenomenon, etc. For example, two different sensors positioned in a field may measure sun intensity. While properly operating, both sensors may provide similar measured values of the sun intensity. However, if one of the sensors is malfunctioning, is shaded by debris blowing in the wind, and/or for other reasons, the provided data may conflict with provided data from another sensor. Because predictions of future states may require accurate information, the accuracy of the predictions may be negatively impacted if inaccurate measurements are used in the predictions of the future states.

In general, embodiments disclosed herein may provide methods, systems, and/or devices for managing conflicting policies and data used in simulations. Policies may be keyed to predicted states, and predictions of the predicted states may result in the policies being invoked. A predicted state may be obtained using at least one inference model, which may generate a plurality of predictions regarding whether a state will occur at a future point in time (e.g., the predicted state).

The plurality of predictions may be analyzed in aggregate using statistical techniques to obtain a statistical characterization (e.g., mean, median, mode, standard deviation) of the plurality of predictions. The statistical characterization may indicate agreement between the plurality of predictions (e.g., variability in the plurality of predictions). The statistical characterization may include quantities which may be compared to criteria included in any number of policies. The criteria may also include requirements corresponding to other information such as the ingest data used to generate the plurality of predictions, characteristics of the plurality of predictions, etc. When criteria for a policy are met, the policy may be invoked, and an action set keyed to the policy may be performed to update operation of any of data processing systems 100 likely to be impacted by the predicted state.

However, the criteria for multiple policies may be met by the statistical characterization and/or other information (e.g., multiple policies may be invoked), and the policies may conflict (e.g., at least one action of the action sets corresponding to the multiple policies may be mutually exclusive and/or may reduce a likelihood of achieving operational goals). To identify conflicting policies within a set of existing policies, a digital twin may be used to generate simulated conditions (e.g., simulated operation of the data processing systems) based on a set of initial conditions. The simulated conditions may be used to obtain a simulated predicted state. Based on the simulated predicted state, it may be determined whether multiple policies from the policy library are invoked.

If multiple policies are invoked, action sets corresponding to each of the policies may be compared to determine whether any actions of the action sets are mutually exclusive and/or conflict for other reasons. If conflicting actions are identified, a new policy may be obtained which may include an action set that overrides the action sets of the conflicting policies.

By doing so, a system in accordance with an embodiment may be used to resolve conflicting policies (e.g., within a set of existing policies) for predicted states by obtaining new policies. The new policies may be added to the set of existing policies and may be invoked during future occurrences of predictions of the predicted states. The action sets corresponding to the new policies may then be performed to manage operation of the data processing systems in a manner that increases a likelihood of the data processing systems providing the computer-implemented services as desired.

To address inconsistencies in sources of data used in simulations (e.g., that generate predictions), the sources of the data may be ranked with respect to trustworthiness. Quantifications for the trustworthiness of each data sources may be established using simulations. For example, when two conflicting values are obtained from two different data sources, simulated operation of the sources of the data may be used to identify which of the data sources is more likely to provide inaccurate information (e.g., may be based on simulated malfunctions, unexpected/accounted for interactions between the data source and the local environment, etc.). Information from the simulations may be extracted and used to quantify the likelihood of the data source providing accurate information. The conflicting values may then be resolved by selected the value from the data source that is ranked as being most trustworthy (e.g., or meeting other criteria).

By doing so, a system in accordance with an embodiment may be more likely to accurate predict the future states of entities within the system. Consequently, application of policies that are keyed to the future states may be more likely to result in desired operation of the system. Accordingly, operation of the data processing systems may be more likely to provide desired the computer-implemented services.

To perform the above-noted functionality, the system of FIG. 1 may include data processing systems 100, and/or management system 102. Data processing systems 100, management system 102, and/or any other type of device not shown in FIG. 1 may perform all, or a portion of, the computer-implemented services independently and/or cooperatively. Each of these components is discussed below.

Data processing systems 100 may include any number and/or type of data processing systems (e.g., 100A-100N), which may include any number of hardware and/or software components configured to provide computer-implemented services. While providing the computer-implemented services, data processing systems 100 may generate data, such as telemetry data, performance data, sensor data, and/or other data related to operation of data processing systems 100. The data generated by data processing systems 100 may be provided to management system 102, which may provide device management services for data processing systems 100.

Management system 102 may include any number and/or type of devices (e.g., other data processing systems, servers, storage devices, user devices) that may be used to provide the device management services. As part of providing the device management services, management system 102 may host a digital twin (e.g., a digital twin model), which may use data regarding initial conditions of data processing systems 100 and/or data regarding other initial conditions which may impact operation of data processing systems 100 (e.g., temperature data, weather data) as ingest. The digital twin may generate simulated conditions (e.g., conditions regarding the operation of data processing systems 100 at a different point in time relative to the initial conditions) as output. As additional data becomes available over time, the digital twin may use data deemed trustworthy to predict future operation of the data processing systems.

If conflicting data is obtained, the conflicts may be resolved by using the data from a data source that is ranked as being most trustworthy. The data processing systems may be ranked for trustworthiness based on simulated operation of the data processing systems. Information from the simulations may be extracted and used to rank the data processing systems (and/or other sources of data used in the digital twin model).

To perform its functionality, management system 102 may (i) obtain data regarding initial conditions of data processing systems 100 (e.g., from data processing systems 100 based on current conditions, historical data regarding operation of data processing systems 100, data from other data sources), (ii) process the data (e.g., fill data gaps, transform the data, extract values from the data) to obtain a set of initial conditions, (iii) feed the set of initial conditions into the digital twin as ingest, (iv) generate a set of simulated conditions as output of the digital twin (e.g., conditions of data processing systems 100 at a different point in time relative to the initial conditions), (v) obtain and screen subsequently obtained data for conflicts, (vi) resolve the conflicts based on trustworthiness of the data sources, (vii) use the resolved data to further operate the digital twin model to further predict future state of the data processing systems, and/or (v) perform other tasks to manage operation of the digital twin.

Additionally, management system 102 may perform inference model management services. To perform inference model management services, management system 102 may train and/or host any number and/or type of inference models trained to generate inferences (e.g., predictions). The inference models may be trained using training data provided to management system 102 by data processing systems 100, training data based on simulated data generated by the digital twin, and/or other training data. The inference models may use simulated conditions generated by the digital twin as input data and generate predictions regarding whether simulated predicted states will occur as output.

To perform its functionality, management system 102 may (i) use training data to train any number of inference models, (ii) feed a set of simulated conditions obtained from the digital twin into at least one of the inference models as ingest, (iii) generate a plurality of predictions indicating whether a simulated predicted state will occur (e.g., at a point in time of the simulated conditions, at any future point in time), (iv) perform, based on a set of existing policies that define how data processing systems 100 are to operate, a policy identification process to determine whether the simulated predicted state invokes any number of policies (e.g., of a policy library), and/or (v) identify whether any of the policies invoked by the simulated predicted state are conflicting (e.g., actions included in action sets keyed to the policies are mutually exclusive).

If conflicting policies are identified, management system 102 may (i) initiate generation of a new policy, (ii) update the set of existing policies with the new policy so that the new policy is invoked during any future occurrence of predictions of the predicted state, (iii) in an occurrence of predictions of the predicted state: perform, based on the new policy, at least a portion of an action set keyed to the new policy to update operation of data processing systems 100, and/or (iv) perform other tasks to manage operation of data processing systems 100.

For example, data processing systems 100 may include any number of unmanned aerial vehicles (e.g., drones) programmed to perform agricultural management services (e.g., to spray pesticide on a field). Initial conditions of the drones may be obtained from any number of sensors (e.g., temperature sensors, humidity sensors, rain gauges, wind sensors) which indicate weather conditions in a geographic location in which the drones are operating. A manner of operation of the drones may be based on any number of existing policies that are keyed to various weather conditions and/or states predicted by the at least one inference model.

The initial conditions may be used to generate predictions by at least one inference model hosted by management system 102 indicating an impending thunderstorm is predicted to damage the drones. Based on a type of state (e.g., a thunderstorm), a first policy may be invoked. The first policy may be invoked by an occurrence of predictions generated by at least one inference model meeting first criteria for first policy implementation. The first policy may indicate that the drones are to spray pesticides before the thunderstorm is predicted to occur.

However, a second policy may also be invoked based on the same initial conditions (e.g., predictions generated by the at least one inference model may meet second criteria for second policy implementation). The second policy may indicate that the drones are to spray pesticides after the thunderstorm is predicted to occur and thus, may conflict with the first policy. Conflicting policies may occur in an existing set of policies due to undetected redundancies in a policy library, human error when keying action sets to policies, and/or any other reason. For example, multiple types of policies in the existing set of policies may be keyed to a predicted state (e.g., intra-device risk management policies, cluster policies, geographical policies), which may result in conflicting policies (e.g., if different types of policies include conflicting action sets).

To resolve conflicting policies in a policy library, a digital twin may be used to generate simulated conditions based on the initial conditions. The simulated conditions may be used by the at least one inference model to generate simulated predicted states. A policy identification process may be performed to identify policies which may be invoked by the simulated predicted states, and if multiple policies are invoked for the same simulated predicted state, conflicts between the policies may be identified and resolved.

For example, to resolve the conflict between the first policy and the second policy invoked by the impending thunderstorm, a new policy may be generated by management system 102 including an action set which overrides the action sets corresponding to the first policy and the second policy. For example, the new policy may indicate that half of the drones are to spray pesticide before the occurrence of the predicted thunderstorm, and the other half of the drones are to spray pesticide after the occurrence of the predicted thunderstorm.

Thus, device management services for data processing systems 100 may be provided by management system 102. By doing so, simulated conditions may be generated by a digital twin based on initial conditions, and the simulated conditions may be used to perform a policy identification process to identify conflicting policies in a set of existing polices. Based on the results of the analysis, a new policy may be obtained to resolve conflicts between policies, and an action set keyed to the new policy may be performed when invoked by predictions of a predicted state. As a result, computer-implemented services may be provided which are more reliable and less likely to be interrupted and/or delayed.

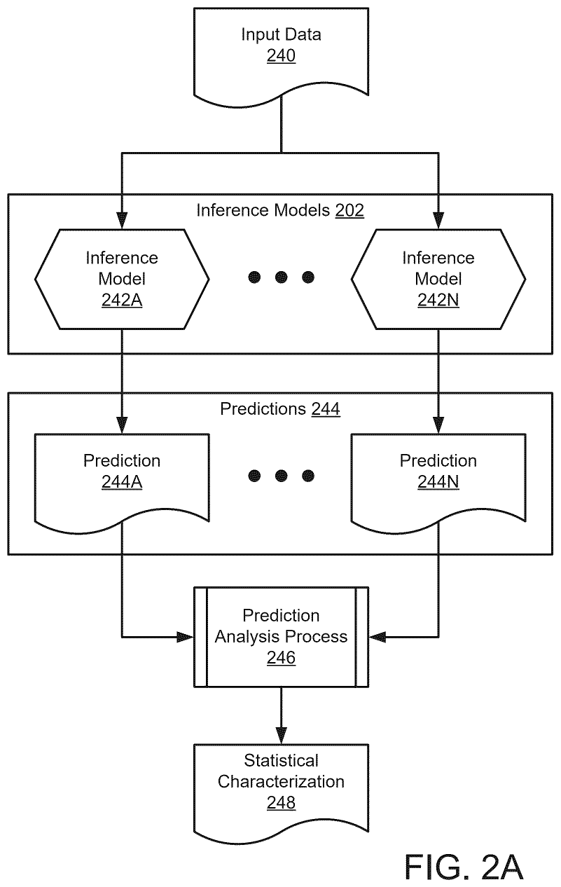

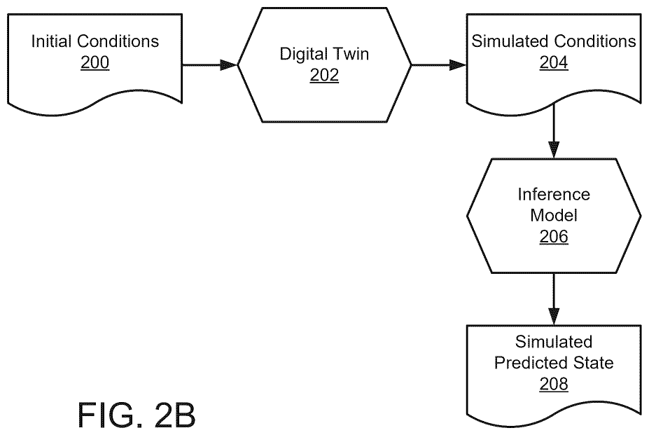

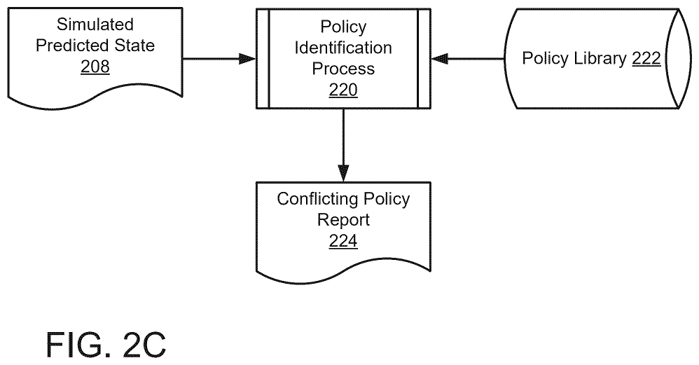

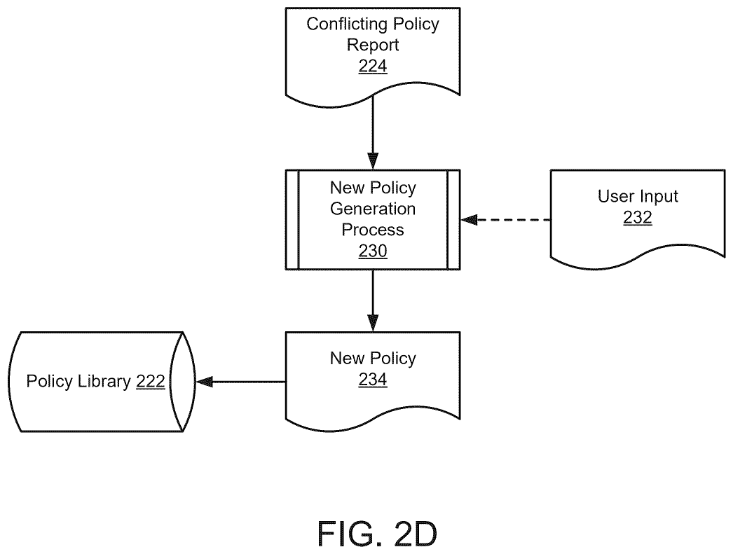

When providing their functionality, any of data processing systems 100, and/or management system 102 may perform all, or a portion, of the processes, interactions, and methods illustrated in FIGS. 2A-3 and 5-6.

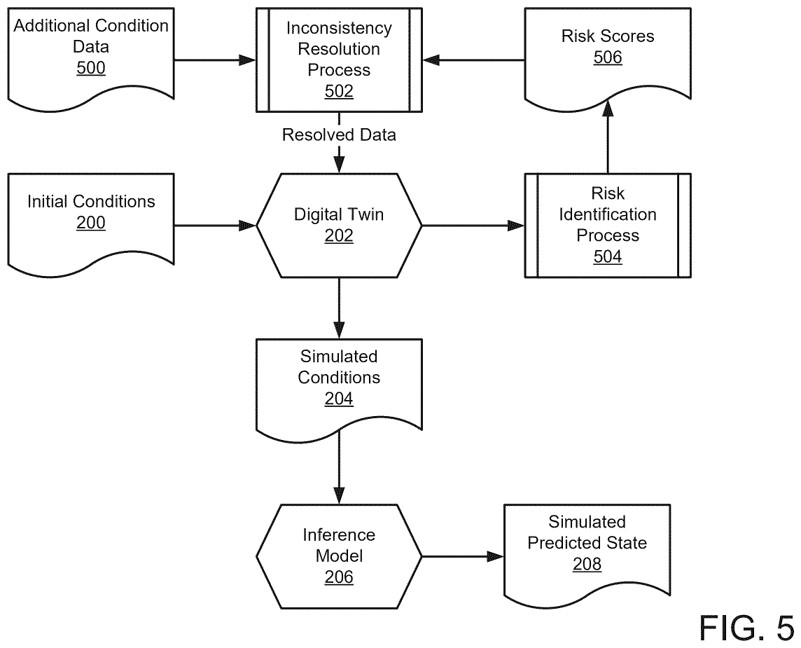

Any of data processing systems 100 and/or management system 102 may be implemented using a computing device (also referred to as a data processing system) such as a host or a server, a personal computer (e.g., desktops, laptops, and tablets), a “thin” client, a personal digital assistant (PDA), a Web enabled appliance, a mobile phone (e.g., Smartphone), and edge device, an embedded system, local controllers, an edge node, and/or any other type of data processing device or system. For additional details regarding computing devices, refer to FIG. 5.

Any of the components illustrated in FIG. 1 may be operably connected to each other (and/or components not illustrated) with communication system 104. Communication system 104 may facilitate communications between the components of FIG. 1. In an embodiment, communication system 104 includes one or more networks that facilitate communication between any number of components. The networks may include wired networks and/or wireless networks (e.g., and/or the Internet). The networks and communication devices may operate in accordance with any number and types of communication protocols (e.g., such as the Internet protocol).

While illustrated in FIG. 1 as including a limited number of specific components, a system in accordance with an embodiment may include fewer, additional, and/or different components than those illustrated therein. For example, while the system of FIG. 1 shows a single management system (e.g., 102), it will be appreciated that the system may include any number of management systems. Likewise, while data processing systems 100 have been discussed as being example data sources, it will be appreciated that other sources of data may also be present (e.g., independent sensors/devices).

To further clarify embodiments disclosed herein, data flow diagrams in accordance with an embodiment are shown in FIGS. 2A-2D. In these diagrams, flows of data and processing of data are illustrated using different sets of shapes. A first set of shapes (e.g., 200, 204) is used to represent data structures, a second set of shapes (e.g., 220, 230) is used to represent processes performed using and/or that generate data, and a fourth set of shapes (e.g., 202, 206) is used to represent models (e.g., inference models, digital twins). Arrows may be shown in dashing to illustrate that use of at least a portion of the data included in a data structure may be optional (e.g., may be used, used in part, and/or omitted when performing a process).

Turning to FIG. 2A, a first data flow diagram in accordance with an embodiment is shown. The first data flow diagram may illustrate data used in and data processing performed in invoking a policy. The policy may be invoked, at least in part, by obtaining a statistical characterization using a plurality of predictions generated using at least one inference model.

To obtain the statistical characterization, input data 240 may be used as ingest to generate predictions using inference models (e.g., inference models 242). Inference models 242 may be hosted by a management system (e.g., management system 102, not shown) responsible for managing operation of data processing systems used to provide computer-implemented services (e.g., data processing systems 100, not shown). Input data 240 may include any type and/or quantity of data, including data generated by data processing systems 100 (e.g., collected using sensors, telemetry data, performance data) and/or data from any other data source (e.g., databases, other management systems, other data processing systems).

Input data 240 may be provided to inference models 242 and used as ingest to generate predictions. Inference models 242 may include any type (e.g., machine learning, decision tree, quantile regression, deterministic simulation, computationally-driven simulation, dynamic simulation, analytical simulation) and/or quantity of inference models (e.g., 242A-242N). Inference models 242 may be trained using training data which defines goals for predictions made by the inference models. Parameters of the inference models may be selected using an optimization process (e.g., an objective function may be defined in terms of the training data and predictions made by the inference models, and a global optimization method such as gradient descent may be used to identify parameters that most faithfully reproduce the trends in the training data).

Once the parameters of an inference model (e.g., inference model 242A) are set, then the inference model may be used to make predictions. A single inference model (e.g., 242A) may be used to generate predictions and/or a plurality of inference models (e.g., 242A-242N) may be used to generate predictions. Differences in model type, training data, and/or the optimization process may result in variability between the predictions made by the inference models, even when the predictions are generated using the same (and/or substantially the same) input dataset. Additionally, stochastic elements (e.g., random variance in one or more parameters over time) may result in prediction variability (e.g., within a single model and/or simulation) for a given set of conditions.

The input dataset used as ingest for inference models 242 (e.g., input data 240) to generate predictions may be substantially the same for each prediction. For example, substantially the same input data may include criteria which permit up to a 10% difference in the input data (e.g., at least 90% of the input data is the same). In a second example, the criteria may indicate that the input data may only differ by 5% to be considered substantially the same (e.g., at least 95% of the input data is the same). In a third example, the criteria may indicate that the input data may differ by 25% to be considered substantially the same (e.g., at least 75% of the input data is the same).

Input data 240 may be ingested by inference models 242, and predictions 244 may be generated as output. Predictions 244 may include a plurality of predictions (e.g., 244A-244N) generated by respective inference models that each indicate whether a state will occur at any future point in time (e.g., a predicted state). The predicted state may include any type of state and at least a portion of the predicted state may be interpreted as an event (e.g., a sandstorm, wind, a temperature increase). For example, predictions 244 may include predicted states which may impact the operation of data processing systems 100, such as changes in temperature, resource availability (e.g., forecasted changes in power supply and/or demand), weather conditions (e.g., rain, hail, wind), and/or any other events which may impact the devices.

For example, data processing systems 100 may include edge devices managed by management system 102, which may include smart streetlights. The smart streetlights may be implemented to conserve power by adjusting the amount of light generated based on data collected by sensors. The data collected by the sensors may include data regarding brightness, humidity, motion, temperature, etc. The data may be provided to management system 102 and used, at least in part, as input data for a plurality of inference models used to generate predictions regarding the occurrence of states which may impact the operation of the smart streetlights.

The plurality of predictions (e.g., predictions 244A-244N) may be used to perform prediction analysis process 246. During prediction analysis process 246, predictions 244 may be analyzed in aggregate to obtain a statistical characterization (e.g., statistical characterization 248) regarding agreement in the plurality of predictions. The statistical characterization may be obtained using any type and/or quantity of statistical methods (e.g., techniques, calculations, data fitting), including averaging, population distribution calculations, hypothesis testing, regression, analysis of variance, and/or any other type of statistical methods. The statistical characterization may include a mean, median, mode, and/or standard deviation for predictions 244.

Continuing with the above example, the at least one inference model may generate predictions based on the sensor data and/or data from other sources regarding an increase in temperature which may affect operation of 100 smart streetlights (e.g., the operation may be impacted to an undesirable degree if the operation continues in the current operating state). For example, temperature data collected by the sensors and temperature data collected from weather satellites may be used as input data for 20 inference models. Of the 20 inference models, 5 may generate predictions indicating the temperature will affect operation of 60 smart streetlights, 10 may generate predictions indicting the temperature will affect operation of 80 smart streetlights, 3 may generate predictions indicating the temperature will affect operation of 75 smart streetlights, and 2 may generate predictions indicting the temperature will affect operation of 10 smart streetlights.

A prediction analysis process may be used to analyze the predictions using statistical methods to obtain statistical characterizations including a median (e.g., 77.5 smart streetlights will be affected) and a standard deviation (e.g., 21.3 smart streetlights).

Statistical characterization 248 may be used, at least in part, in invoking a policy (e.g., from a policy library, not shown). The policy may include an action set keyed to the predicted state (e.g., from predictions 244) and the action set may be usable to update operation of one or more data processing systems that are likely to be impacted by the predicted state. If statistical characterization 248 meets criteria indicating agreement in the plurality of predictions (e.g., a quantity of the statistical characterization falls within a range indicated by the criteria), the policy may be invoked (e.g., implementation of the policy may be triggered) based on a type of the predicted state.

Thus, by implementing the data flow shown in FIG. 2A, a system in accordance with embodiments disclosed herein may be used to invoke a policy using, at least in part, a statistical characterization of a plurality of predictions generated by at least one inference model. The input data used to generate each prediction may be substantially the same, though differences in inference model types, training, and/or optimization may result in variability in the predictions. The variability in the predictions may be analyzed using statistical methods.

Turning to FIG. 2B, a second data flow diagram in accordance with an embodiment is shown. The second data flow diagram may illustrate data used in and data processing performed in obtaining a simulated predicted state based on initial conditions.

Obtaining a simulated predicted state (e.g., simulated predicted state 208) may include processes performed by a management system (e.g., management system 102, not shown) responsible for managing operation of data processing systems used to provide computer-implemented services (e.g., data processing systems 100, not shown). Obtaining simulated predicted state 208 may be initiated by obtaining a policy.

In a first example, a first policy may be obtained (e.g., by management system 102, not shown) to manage impact of a state not contemplated by the set of existing policies. For example, the first policy may be generated to mitigate and/or prevent damage to the data processing systems based on a first type of predicted state which is not explicitly accounted for in the existing set of policies. The first policy may, therefore, be intended to be added to the set of existing policies. Prior to adding the first policy to the set of existing policies, processes may be performed to proactively identify and/or resolve conflicts between the first policy and any number of other policies in an existing set of policies (e.g., from a policy library, not shown).

However, initial conditions which invoke the first policy based on a first type of predicted state may also invoke a conflicting policy from the policy library (e.g., the conflicting policy may be based on a second type of predicted state which may include similar initial conditions). Similarly, the first policy may be intended to manage impact of a first state not contemplated by the set of existing policies, though a second policy keyed to the first state may already be included in the set of existing policies (e.g., the second policy keyed to the first state may already exist, yet the first policy may be generated due to an oversight and/or other error).

In a second example, a first policy may be obtained following the first policy being invoked by predictions of a predicted state. Prior to implementing the first policy (e.g., performing the action set keyed to the first policy), it may be verified that the predicted state does not invoke a conflicting policy (e.g., including a conflicting action set). In doing so, a likelihood that management system 102 attempts to initiate performance of conflicting action sets may be reduced, which may reduce a likelihood of damage to the data processing systems (e.g., by performing an undesired action set, due to an inability of the data processing systems to parse instructions for performing conflicting action sets). In this second example, the first policy may be obtained by obtaining a statistical characterization of a plurality of predictions (e.g., generated by at least one inference model) that meets criteria indicating the predicted state will occur, and identifying the first policy from the set of existing policies based on a type of the predicted state to which the first policy is associated. Refer to the description of FIG. 2A for additional details regarding obtaining the statistical characterization.

Once the policy is obtained, a policy analysis process may be performed using at least the policy and a digital twin (e.g., digital twin 202) to determine whether the policy conflicts with any policies of a set of existing policies. To perform the policy analysis process, initial conditions 200 may be obtained and used as ingest for digital twin 202. Initial conditions 200 may include any type and/or quantity of data, including data generated by data processing systems 100 (e.g., collected using sensors, telemetry data, performance data) and/or data from any other data source (e.g., databases, other management systems, other data processing systems). Initial conditions 200 may include data regarding current operating conditions of data processing systems 100, and/or may include historical data regarding past operating conditions of data processing systems 100.

Initial conditions 200 may have been previously used to obtain the policy and may be intended to represent operational conditions for data processing systems likely to be impacted by the predicted state. For example, in a first instance when the policy has been generated and is intended to be added to the set of existing policies, the initial conditions may represent operational conditions of the data processing systems keyed to the predicted state which may invoke the policy. In a second instance when the policy is an existing policy and is intended to be implemented, the initial conditions may represent operational conditions of the data processing system keyed to the predicted state which have invoked the policy.

Initial conditions 200 may be provided to digital twin 202 and used as ingest to generate a set of simulated conditions (e.g., simulated conditions 204) as output. Digital twin 202 may include a model trained to simulate operation of data processing systems 100 under a range of possible environmental conditions and/or other scenarios defined by initial conditions 200 to generate simulated conditions 204. Simulated conditions 204 may be intended to represent operation of data processing systems 100 at a point in time different from a point in time of the initial conditions. The point in time modeled by simulated conditions 204 may vary based on the type of predicted state, a type of data processing system being simulated, and/or other factors.

For example, initial conditions 200 may include wind speeds obtained from sensor data collected for a geographic location. The geographic location may include four quadrants, and one drone may operate in each quadrant. Wind speeds for each quadrant of the geographic location may be collected by the drones, and used as ingest by digital twin 202. Digital twin 202 may simulate wind speeds in one hour for each quadrant, resulting in the generation of simulated conditions 204 which may include four simulations (e.g., one corresponding to each of the four quadrants).

Simulated conditions 204 may be used as input for at least one inference model (e.g., inference model 206) to obtain simulated predicted state 208. Inference model 206 may include any type and/or quantity of inference models (e.g., machine learning, decision tree, quantile regression, deterministic simulation, analytical simulation). To obtain simulated predicted state 208, simulated conditions 204 may be ingested by inference model 206, and any number of predictions may be generated as output. Each of the predictions may indicate whether a state will occur in a future (e.g., at any future point in time, over a duration of time beginning at any future point in time) based on simulated conditions 204.

For example, the predictions may include predictions regarding a state (e.g., simulated predicted state 208) which may impact the operation of data processing systems 100 if data processing systems 100 were to operate under simulated conditions 204. Simulated predicted state 208 may include states such as changes in temperature, resource availability (e.g., forecasted changes in power supply and/or demand), weather conditions (e.g., rain, hail, wind, thunderstorms), and/or any other states which may impact the devices.

Continuing with the above example, simulated conditions 204 including the four simulated wind speeds may be used as input for an inference model. The inference model may generate predictions regarding whether any of the simulated wind speeds indicate a future occurrence of a windstorm (e.g., the simulated predicted state). For example, the inference model may generate predictions indicating that the simulated wind speed of the first quadrant meets criteria for a simulated predicted windstorm. Based on the simulated predicted windstorm, a corresponding policy may be identified to manage operation of a first drone (not shown). Refer to the discussion of FIG. 2C for additional details regarding policy identification based on a simulated predicted state.

While described with respect to obtaining the simulated predicted state using an inference model, it will be appreciated that the digital twin (e.g., 202) may be used to generate the simulated predicted state without the use of an inference model without departing from embodiments disclosed herein.

Thus, by implementing the data flow shown in FIG. 2B, a system in accordance with embodiments disclosed herein may be used to obtain a simulated predicted state based on simulated conditions generated by a digital twin. The simulated conditions generated by the digital twin may be intended to represent the operational conditions of the data processing systems at a future point in time based on a set of initial conditions. An inference model may then be used to generate the simulated predicted state using the simulated conditions as input.

Turning to FIG. 2C, a third data flow diagram in accordance with an embodiment is shown. The third data flow diagram may illustrate data used in and data processing performed in performing at least a portion of a policy analysis process based on the simulated predicted state described in FIG. 2B. A conflicting policy report may be obtained during the policy analysis process.

To obtain the conflicting policy report, policy identification process 220 may be performed using simulated predicted state 208 and policy library 222. During policy identification process 220, it may be determined whether a state indicated by simulated predicted state 208 invokes any number of policies included in policy library 222. Policy library 222 may include a database and/or any other type of storage which includes a set of existing policies including any number and/or type of policies (e.g., device risk management policies, geographical policies) keyed to any type of state (e.g., wind, hail, power outages) which may impact devices (e.g., data processing systems 100, not shown).

Simulated predicted state 208 may be used as a key to perform a look up in policy library 222 to identify any of the set of existing policies that are invoked (e.g., that are keyed to at least a portion of simulated predicted state 208). For example, simulated predicted state 208 may invoke a first policy and a second policy from policy library 222. A simulated predicted state (e.g., 208) may be used to proactively determine whether conflicting policies are present in policy library 222 prior to an occurrence of a predicted state invoking a policy and initiating performance of a corresponding action set.

If it is determined during policy identification process 220 that more than one policy from policy library 222 is invoked (e.g., the first policy and the second policy), it may be determined whether the first policy conflicts with the second policy. Policies may be conflicting when actions in the action sets corresponding to each of the policies include at least one mutually exclusive action and/or reduce a likelihood of meeting operational goals for data processing systems 100. To determine whether the policies are conflicting, the corresponding action sets may be compared to identify any instances of conflicting actions.

For example, a first action set corresponding to the first policy may be compared to a second action set corresponding to the second policy to identify any instances of mutually exclusive (e.g., conflicting) actions. For example, the first policy and the second policy may be keyed to an occurrence of a predicted temperature increase which may impact the operation of drones. The first action set may include a command for the drones to continue operation, and the second action set may include a command for the drones to cease operation until the predicted temperature falls below a temperature threshold. It may be determined that the first policy conflicts with the second policy due to the contradictory nature of the commands included in the action sets.

As part of performing policy identification process 220, a conflicting policy report may be generated (e.g., conflicting policy report 224). Conflicting policy report 224 may include data regarding identified conflicting policies, such as (i) an indication of the identified conflicting policies invoked by simulated predicted state 208, (ii) a list of conflicting actions in the action sets corresponding to the identified conflicting policies, (iii) data indicating portions of the initial conditions and/or simulated conditions which invoked the identified conflicting policies, and/or (iv) other information regarding the identified conflicting policies. The report may include human-readable text (e.g., for review by a subject matter expert (SME) and generated by a large language model (LLM)) and/or machine-readable code (e.g., for automated and/or semi-automated review of the report). For additional details regarding the use of conflicting policy report 224, refer to FIG. 2D.

Thus, by implementing the data flow shown in FIG. 2D, a system in accordance with embodiments disclosed herein may be used to identify policies which may be invoked based on a simulated predicted state. Action sets corresponding to the policies may be compared to identify any instances of conflicting actions. A conflicting policy report may be obtained including information regarding the identified policies and/or conflicting actions.

Turning to FIG. 2D, a fourth data flow diagram in accordance with an embodiment is shown. The fourth data flow diagram may illustrate data used in and data processing performed in obtaining a new policy in response to an identification of conflicting policies in a conflicting policy report. The new policy may be used to update a set of existing policies (e.g., in a policy library).

To obtain a new policy (e.g., new policy 234), new policy generation process 230 may be performed. During new policy generation process 230, it may be determined that a new policy (e.g., new policy 234) is to be generated to resolve the conflicting policies indicated by conflicting policy report 224. New policy 234 may be adapted to, when invoked by an occurrence of a predicted state (e.g., the predicted state which invokes the identified conflicting policies), resolve a conflict between the identified conflicting policies of policy library 222.

To resolve the conflict, new policy 234 may include an action set which overrides action sets included in the conflicting policies. For example, new policy 234 may include an action set to update operation of data processing systems likely to be impacted by the predicted state to hedge against a risk of an undesired outcome from the occurrence of the predicted state. The action set may include any portion of the actions included in the conflicting policies, and/or may include other actions not included in the conflicting polices.

Generating new policy 234 may include automated, semi-automated, and/or manual methods. For example, conflicting policy report 224 may be generated based on user input (e.g., via manual methods), and/or partially based on user input (e.g., via semi-automated methods). User input (e.g., user input 232) may be used to generate new policy 234 by providing conflicting policy report 224 to a user (e.g., a SME), who may read conflicting policy report 224 and provide a response (e.g., to a system responsible for managing policy library 222, such as management system 102, not shown). The response may include (i) new policy 234, (ii) instructions for management system 102 usable to generate new policy 234, and/or (iii) other user input which may be used, at least in part, to generate new policy 234.

New policy 234 may also be generated by a computing device (e.g., via automated methods) and/or partially by the computing device (e.g., via semi-automated methods). Generating new policy 234 using the computing device may include using a software application, inference model, and/or any other type of program hosted by the computing device to generate new policy 234 based, at least in part, on conflicting policy report 224.

New policy 234 may be used to update the set of existing policies included in policy library 222 so that new policy 234 is invoked during any future occurrence of predictions of the predicted state (e.g., by adding meta data to new policy 234 which allows new policy 234 to override the conflicting policies, by removing the conflicting policies from policy library 222). Thus, in response to an occurrence of the predicted state, the action set of new policy 234 may be performed to update operation of one or more data processing systems that are likely to be impacted by the state. Computer-implemented services may then be provided using the updated operation of the one or more data processing systems.

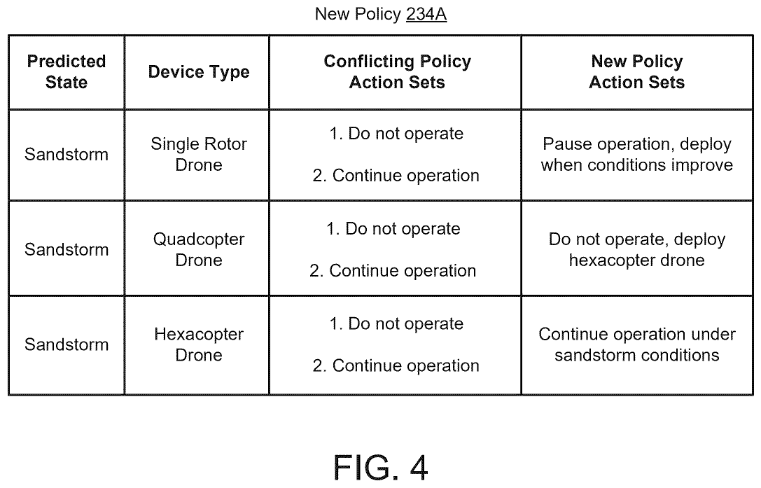

Thus, by implementing the data flow shown in FIG. 2D, a system in accordance with embodiments disclosed herein may be used to update a set of existing policies to include a new policy. The new policy may resolve a conflict between conflicting policies by including an action set which overrides action sets of the conflicting polices. In doing so, the new policy may be invoked and the corresponding action set may be performed, which may result in computer-implemented services of an improved quality and a decreased likelihood of being interrupted and/or delayed. Refer to FIG. 4 for an example of a new policy.

Any of the processes illustrated using the second set of shapes may be performed, in part or whole, by digital processors (e.g., central processors, processor cores, etc.) that execute corresponding instructions (e.g., computer code/software). Execution of the instructions may cause the digital processors to initiate performance of the processes. Any portions of the processes may be performed by the digital processors and/or other devices. For example, executing the instructions may cause the digital processors to perform actions that directly contribute to performance of the processes, and/or indirectly contribute to performance of the processes by causing (e.g., initiating) other hardware components to perform actions that directly contribute to the performance of the processes.

Any of the processes illustrated using the second set of shapes may be performed, in part or whole, by special purpose hardware components such as digital signal processors, application specific integrated circuits, programmable gate arrays, graphics processing units, data processing units, and/or other types of hardware components. These special purpose hardware components may include circuitry and/or semiconductor devices adapted to perform the processes. For example, any of the special purpose hardware components may be implemented using complementary metal-oxide semiconductor based devices (e.g., computer chips).

Any of the data structures illustrated using the first and third set of shapes may be implemented using any type and number of data structures. Additionally, while described as including particular information, it will be appreciated that any of the data structures may include additional, less, and/or different information from that described above. The informational content of any of the data structures may be divided across any number of data structures, may be integrated with other types of information, and/or may be stored in any location.

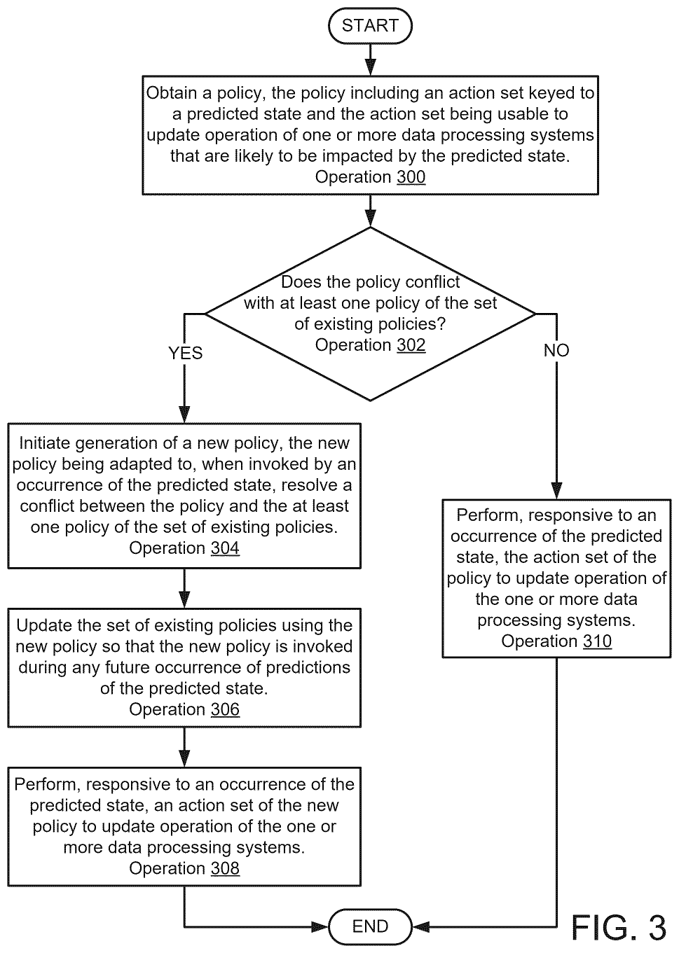

As discussed above, the components of FIGS. 1-2D may perform various methods to manage conflicting policies. FIG. 3 illustrates a method that may be performed by the components of the system of FIGS. 1-2D. In the diagram discussed below and shown in FIG. 3, any of the operations may be repeated, performed in different orders, and/or performed in parallel with or in a partially overlapping in time manner with other operations.

Turning to FIG. 3, a flow diagram illustrating a method of managing conflicting policies in accordance with an embodiment is shown. The method may be performed, for example, by any of the components of the system of FIG. 1, and/or any other entity without departing from embodiments disclosed herein.

At operation 300, a policy may be obtained, the policy including an action set keyed to a predicted state and the action set being usable to update operation of one or more data processing systems that are likely to be impacted by the predicted state. Obtaining the policy may include generating the policy to manage impact of a state not contemplated by the set of existing policies, the policy being intended to be added to the set of existing policies. Generating the policy may include (i) identifying a state (e.g., based on historic operating conditions, based on simulated operating conditions) which is not included in the set of existing policies, (ii) generating the policy based on the identified state to prevent and/or mitigate an impact of the occurrence of the state (e.g., by an inference model, by a SME), (iii) obtaining instructions from another entity for generating the policy (e.g., a computing device, a SME), and/or (iv) other methods.

Obtaining the policy may also include obtaining a prediction that indicates the predicted state will occur, the prediction being generated by at least one inference model. Obtaining the prediction may include (i) obtaining input data (e.g., regarding an initial condition of the data processing systems, regarding initial conditions and/or events which may impact the state of the data processing systems), (ii) using the input data as ingest for the at least one inference model (e.g., feeding the input data into the at least one inference model to generate any number of predictions), (iii) obtaining a plurality of predictions as output of the at least one inference model (e.g., generating the plurality of predictions by the at least one inference model using the input data), (iv) analyzing the plurality of predictions to obtain a statistical characterization regarding agreement in the plurality of predictions, (v) making a determination regarding whether the statistical characterization, input data, and/or the plurality of predictions meet requirements included in criteria for invoking the policy, and/or (vi) other methods.

Obtaining the input data may include (i) collecting the input data (e.g., via sensors operably connected to the data processing systems, via generation of the input data by inference models hosted by the data processing systems), (ii) receiving the input data from the data processing systems (e.g., via a message, by reading the input data from a storage used by the data processing systems to store data), (iii) receiving the input data from other devices (e.g., via a message), (iv) performing a look up in a database for data relevant to generating the plurality of predictions, and/or (v) other methods.

Analyzing the plurality of predictions may include (i) aggregating the plurality of predictions into a dataset, (ii) using statistical methods to obtain the statistical characterization of the dataset, (iii) proving the dataset to another device and receiving the statistical characterization in response, and/or (iv) other methods.

Using statistical methods may include performing statistical calculations (e.g., averaging, population distribution calculations, hypothesis testing, regression, analysis of variance) to obtain the statistical characterization. The statistical characterization may include a mean, median, mode, standard deviation and/or any other type of statistical characterization of the dataset usable to determine agreement in the plurality of predictions.

Making the determination may include (i) identifying at least one quantity of the statistical characterization (e.g., analyzing the statistical characterization to extract a numerical value and/or other type of metric), (ii) identifying a requirement indicated by the criteria that corresponds to the at least one quantity, (iii) analyzing the at least one quantity using the requirement to obtain at least a partial result indicating whether the statistical characterization meets the criteria, and/or (iv) other methods. Portions of the input data and/or information related to the plurality of predictions may also be compared to corresponding requirements included in the criteria to determine whether the criteria are met.

If it is determined that the statistical characterization meets criteria, a policy may be identified from the set of existing policies, the policy being based on a type of the predicted state to which the policy is associated. Identifying the policy may include (i) using the type of the predicted state as a key to perform a look up (e.g., in a policy library) to identify any of the set of existing policies associated with the predicted state, (ii) providing the predicted state to another entity and receiving the policy in response (e.g., a computing device, a SME), and/or (iii) other methods.

At operation 302, it may be determined whether the policy conflicts with at least one policy of the set of existing policies. Determining whether the policy conflicts with at least one policy of the set of existing policies may include performing a policy analysis process using at least the policy and a digital twin, the digital twin being trained to generate simulated conditions.

Performing the policy analysis process may include (i) inputting a set of initial conditions into the digital twin as ingest, the initial conditions being previously used to obtain the policy and the initial conditions being intended to represent operational conditions for data processing systems likely to be impacted by the predicted state (e.g., feeding the set of initial conditions into the digital twin, providing the set of initial conditions to another entity responsible for operation of the digital twin), (ii) obtaining a set of simulated conditions from the digital twin as output, the set of simulated conditions being intended to represent operation of the data processing systems at a point in time different from a point in time of the initial conditions (e.g., generating, based on the set of initial conditions, the set of simulated conditions, obtaining the output from another entity responsible for operating the digital twin, reading the set of simulated conditions from storage following generation by the digital twin), (iii) making, using at least the simulated conditions, a determination regarding whether the policy and at least a second policy from the set of existing policies are invoked, (iv) if it is determined that the policy and at least the second policy are invoked, comparing the action set to action sets corresponding to the at least the second policy to identify any instances of conflicting actions, and/or (v) other methods.

Making the determination may include (i) using the set of simulated conditions as input for at least one inference model to obtain a simulated predicted state, (ii) using the simulated predicted state as a key to perform a look up to identify any of the set of existing policies that are invoked, and/or (iii) other methods. Using the set of simulated conditions to obtain a simulated predicted state may include methods similar to those described with respect to obtaining a prediction that indicates the predicted state will occur in operation 300 (e.g., using the set of simulated conditions as ingest for the at least one inference model, obtaining a plurality of predictions as output of the at least one inference model, analyzing the plurality of predictions to obtain a second statistical characterization regarding agreement in the plurality of predictions, comparing at least the second statistical characterization to criteria. Using the simulated predicted state as a key may include methods similar to those described with respect to identifying the policy in operation 300 (e.g., using the simulated predicted state as a key to perform a look up in the policy library to identify any of the set of existing policies associated with the simulated predicted state, providing the simulated predicted state to another entity and receiving the policy in response).

Comparing the action set to action sets corresponding to the at least the second policy may include (i) parsing the action sets to obtain a list of actions corresponding to each policy, (ii) identifying any instances of conflicting actions (e.g., mutually exclusive actions) in the lists of actions, (iii) providing the action sets to another entity and receiving an identification of any instances of conflicting actions in response, (iv) generating a conflicting policy report including any instances of conflicting actions which were identified, and/or (iv) other methods.

If it is determined that the policy conflicts with at least one policy of the set of existing policies (e.g., the determination is “Yes” at operation 302), then the method may proceed to operation 304.

At operation 304, generation of a new policy may be initiated, the new policy being adapted to, when invoked by an occurrence of the predicted state, resolve a conflict between the policy and the at least one policy of the set of existing policies. Initiating generation of the new policy may include (i) providing the initial conditions, simulated conditions, and/or simulated predicted state to a SME, (ii) generating the new policy (e.g., via an automated system such as a generative inference model, via a semi-automated system including user input and an automated system), and/or (iii) via other methods.

Providing the initial conditions, simulated conditions, and/or simulated predicted state to the SME may include (i) providing the initial conditions, simulated conditions, and/or simulated predicted state as a data package to the SME via a message over a communication system (e.g., a popup interface, an electronic message, a graphical user interface on a device), (ii) storing the initial conditions, simulated conditions, and/or simulated predicted state in a storage architecture shared with the SME and notifying the SME that a new policy is to be generated, (iii) providing the set of conditions to another entity responsible for interacting with the SME, and/or (iv) other methods.

At operation 306, the set of existing policies may be updated using the new policy so that the new policy is invoked during any future occurrence of predictions of the predicted state. Updating the set of existing policies may include (i) replacing the conflicting policies with the new policy (e.g., removing the conflicting policies from the set of existing policies and/or modifying the conflicting policies), (ii) adding meta data to the new policy which allows the action set of the new policy to override the action set of the conflicting policies during any future occurrence of predictions of the predicted state, and/or (iii) other methods.

At operation 308, an action set of the new policy may be performed responsive to an occurrence of the predicted state to update operation of the one or more data processing systems. Performing the action set may include (i) obtaining the action set (e.g., from the SME, from storage, from another entity), (ii) transmitting instructions to the data processing systems, the instructions indicating the actions to be performed based on the action set, (iii) parsing the instructions, (iii) executing the instructions to update the operating state of the data processing systems to an updated operating state, and/or (iv) other methods. Updating the operation of the one or more data processing systems may be performed to hedge against a risk of an undesired outcome from the occurrence of the predicted state.

Computer-implemented services may be provided using the updated operation of the one or more data processing systems. Providing the computer-implemented services using the updated operation of the one or more data processing systems may include (i) initiating performance of functions of the data processing systems in a modified state (e.g., at a reduced power, at a reduced processor frequency), (ii) initiating performance of the functions of the data processing systems in a different location (e.g., in a location where the state is not predicted to occur), (iii) initiating performance of the functions of the data processing systems at a different time (e.g., before and/or after the occurrence of the state), and/or (iv) other methods.

The method may end following operation 308.

Returning to operation 302, if it is determined that the policy does not conflict with at least one policy of the set of existing policies (e.g., the determination is “No” at operation 302), then the method may proceed to operation 310.

At operation 310, the action set of the policy may be performed to update operation of the one or more data processing systems responsive to an occurrence of the predicted state. For example, it may be determined that the policy does not conflict with any other policy of the set of existing policies and, therefore, the action set of the policy may be performed. Performing the action set of the policy may include methods similar to those described with respect to performing the action set in operation 308.

The method may end following operation 310.

Thus, using the methods illustrated in FIG. 3, embodiments disclosed herein may provide systems and methods usable to manage conflicting policies using a digital twin to simulate conditions which may be used to obtain a simulated predicted state. The simulated predicted state may be used as a key to perform a look up in a set of existing policies to determine whether more than one policy is invoked. If more than one policy is invoked, the action sets associated with each policy may be compared to identify any conflicting actions. The identification of conflicting actions may initiate the generation of a new policy to resolve the conflict.

To further clarify embodiments disclosed herein, an example implementation in accordance with an embodiment is shown in FIG. 4. This figure shows a diagram illustrating a new policy in accordance with an embodiment.

Turning to FIG. 4, an example of a new policy (e.g., new policy 234A) is shown. New policy 234A may be organized as a table including a series of columns and rows. A first column may include identifiers indicating a predicted state which may impact operation of one or more data processing systems. For example, the predicted state may include a type of event, including weather events such as a sandstorm. A second column may include identifiers indicating a device type. The device type may include any number and/or type of devices which may be impacted by the predicted state indicated by the first column, including data processing systems such as drones. A third column may include information regarding conflicting policy action sets (e.g., action sets which include at least one mutually exclusive action) which may have been identified in a conflicting policy report (refer to the description of FIG. 2B for additional details regarding the conflicting policy report). A fourth column may include new policy action sets, which may include actions that override the actions of the conflicting policy action sets.

Consider a scenario in which three types of drones (e.g., single rotor drones, quadcopter drones, and hexacopter drones) are used to provide aerial surveying services for a geographic region. To manage operation of the drones, policies keyed to any number of predicted states which may impact the operation of the drones may be stored in a policy library. Using a simulated predicted state (e.g., obtained via methods similar to those described with respect to FIG. 2A), it may be determined that policies keyed to a sandstorm are conflicting.

For example, a predicted sandstorm may invoke two policies of the policy library for the three types of drones. A first policy may include a device risk management policy which may include an action set with a command to not operate the drones in an instance of a predicted sandstorm in order to prevent and/or mitigate damage to the drones. A second policy may include a geographic location policy which may include an action set with a command to continue operation of the drones in an instance of a predicted sandstorm in order to provide the aerial surveying services in the desired geographic region.

In response to the identification of the conflicting policies, a new policy may be generated (e.g., new policy 234A). New policy 234A may include an action set for each type of drone, including (i) a command to pause operation of the single rotor drone until conditions improve (e.g., when risk of damage to the single rotor drone falls below a threshold), (ii) a command to not operate the quadcopter drone and deploy the hexacopter drone as a replacement to provide the aerial surveying services, and/or (iii) a command to continue operation of the hexacopter drone to provide the aerial surveying services. In doing so, a conflict between multiple policies invoked by a predicted event may be resolved.

In addition to resolving conflicts in policies, conflicts in believe regarding the state of the system may be resolved to improve the accuracy of simulation. To further clarify embodiments disclosed herein, a data flow diagram in accordance with an embodiment is shown in FIG. 5. In the diagram, flows of data and processing of data are illustrated using different sets of shapes. A first set of shapes (e.g., 200, 204) is used to represent data structures, a second set of shapes (e.g., 502, 504) is used to represent processes performed using and/or that generate data, and a third set of shapes (e.g., 202, 206) is used to represent models (e.g., inference models, digital twins).

Turning to FIG. 5, a fifth data flow diagram in accordance with an embodiment is shown. The fifth data flow diagram may illustrate data used in and data processing performed in resolving conflicts in belief and use of resolved data in simulation of future states of systems.

To resolve conflicts in belief, as additional condition data 500 is obtained, inconsistency resolution process 502 may be performed. During inconsistency resolution process 502, additional condition data 500 may be screen for inconsistencies. An inconsistency may arise when two portions of data from two different data sources that measure the same characteristic of a system meet criteria, such as a different between the two portions of data exceeding a threshold level.

For example, if two sensors measure sun intensity and both are positioned to make similar measurements, the measurements provided by the two sensors should be consistent. If the measurements are different, then one of the sensors is likely malfunctioning, operating in an unexpected/accounted for manner, is being impacted by an unaccounted for issue in the system (e.g., unaccounted for debris from the environment landing on the sensor depriving it of clear line of sight to the sun/sky/etc.).

When conflicts between portions of data are identified, the conflicts may be resolved using risk scores 506. Risk scores may be quantifications regarding the trustworthiness of sources of data (e.g., trustworthiness of providing accurate data). To resolve the inconsistency, the data sources that provided the portions of data may be ranked. The rankings may then be used to select one of the data sources. For example, a highest ranked data source may be selected.

In addition to ranking based on risk scores, the data sources may also be filtered based on various criteria. For example, only data sources having been operable for minimum or maximum durations of time may be eligible for selection, and/or having other characteristics usable as filtering criteria.

Once the data source is identified, the portion of data from the data source may be used as resolved data (e.g., trustworthy data). The trustworthy data may then be used in further operation of digital twin 202.

For example, during operation of data twin 202, measurements from sensors over time may be used in the operation of digital twin 202. During operation of digital twin 202, operation of the data sources (and/or other entities in a system) may also be simulated to obtain predictions regarding the current operational state of the data sources. Information regarding the operation of the data sources may be extracted and used in risk identification process 504 to obtain risk scores 506.

For example, digital twin 202 may (i) simulate the operation of the data sources overtime to identify future states of the system components, (ii) simulate how an environment is likely to impact the data sources, and/or simulate other activity that may impact a system. Information regarding the predicted operation (e.g., a future state) and impact of the environment (and/or other entities) on the operation of the data sources may be extracted.

During risk identification process 504, the extracted information for a data sources may be used to compute risk scores 506. The risk scores may be calculated using a formula. For example, the formula may output a quantification that reflects the likelihood of the trustworthiness of each data source to provide accurate data. The formula may be, for example, a weighted sum. Different weights may be selected for different pieces of information extracted from the simulation. For example, information regarding (i) the current operational state of a data source, and (ii) environmental impacts on the data source. Different weights may be used to compute a weighted sum of these different pieces of information. The resulting quantification may be normalized and/or otherwise processed to obtain a risk score of risk scores 506 for the data source. Similar processes may be performed to compute risk scores for any number of data sources.

Thus, the resulting simulated conditions 204 may be more likely to be accurate because only resolved data may be used to drive operation of the digital twin model, thereby resolving believe conflicts in the system.

Any of the processes illustrated using the second set of shapes may be performed, in part or whole, by digital processors (e.g., central processors, processor cores, etc.) that execute corresponding instructions (e.g., computer code/software). Execution of the instructions may cause the digital processors to initiate performance of the processes. Any portions of the processes may be performed by the digital processors and/or other devices. For example, executing the instructions may cause the digital processors to perform actions that directly contribute to performance of the processes, and/or indirectly contribute to performance of the processes by causing (e.g., initiating) other hardware components to perform actions that directly contribute to the performance of the processes.

Any of the processes illustrated using the second set of shapes may be performed, in part or whole, by special purpose hardware components such as digital signal processors, application specific integrated circuits, programmable gate arrays, graphics processing units, data processing units, and/or other types of hardware components. These special purpose hardware components may include circuitry and/or semiconductor devices adapted to perform the processes. For example, any of the special purpose hardware components may be implemented using complementary metal-oxide semiconductor based devices (e.g., computer chips).

Any of the data structures illustrated using the first and third set of shapes may be implemented using any type and number of data structures. Additionally, while described as including particular information, it will be appreciated that any of the data structures may include additional, less, and/or different information from that described above. The informational content of any of the data structures may be divided across any number of data structures, may be integrated with other types of information, and/or may be stored in any location.

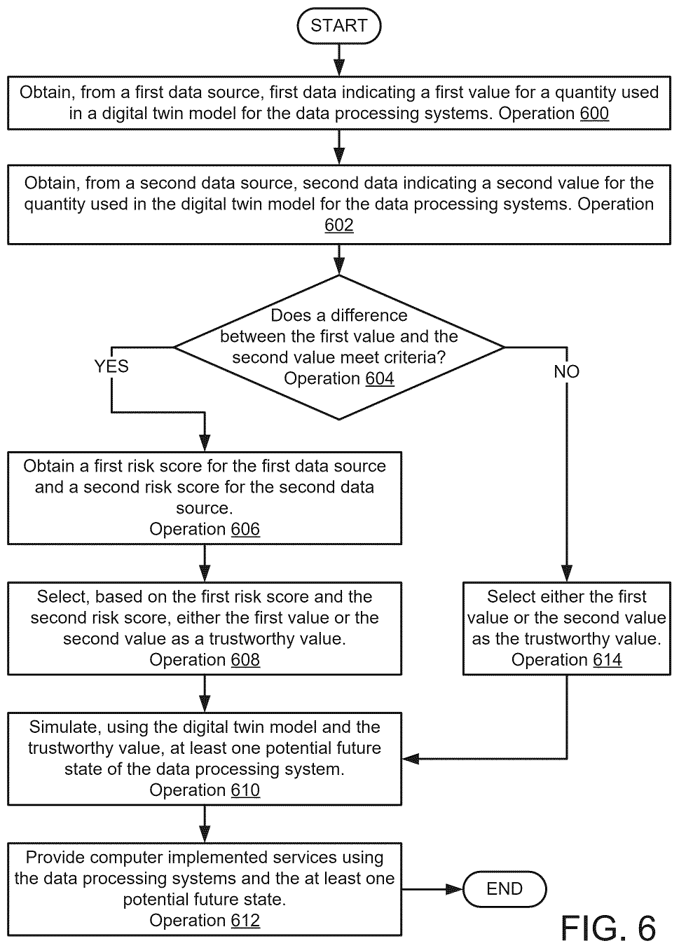

As discussed above, the components of FIGS. 1-2D and 4 may perform various methods to manage conflicting beliefs in the state of a system. FIG. 6 illustrates a method that may be performed by the components of the system of FIGS. 1-2D and 4. In the diagram discussed below and shown in FIG. 6, any of the operations may be repeated, performed in different orders, and/or performed in parallel with or in a partially overlapping in time manner with other operations.

Turning to FIG. 6, a flow diagram illustrating a method of managing conflicting belief in the state of a system in accordance with an embodiment is shown. The method may be performed, for example, by any of the components of the system of FIG. 1, and/or any other entity without departing from embodiments disclosed herein.

At operation 600, first data indicating a first value for a quantity used in a digital twin model for data processing system is obtained from a first data source. The first data may be obtained by reading the first data from storage, receiving the first data from the data source, receiving the first data from another entity, and/or via other methods.

At operation 602, second data indicating a second value for the quantity used in the digital twin model for the data processing system is obtained from a second data source. The second data may be obtained by reading the second data from storage, receiving the second data from the second data source, receiving the second data from another entity, and/or via other methods.

At operation 604, a determination is made regarding whether a difference between the first value and the second value meet criteria. The determination may be made by (i) computing the difference, and (ii) comparing the different to the criteria to see if the criteria is met.

The criteria may include, for example, a threshold amount for the difference. If the difference exceeds the threshold amount, then it may be concluded that the difference meets the criteria.

If the criteria is met, then the method may proceed to operation 606. Otherwise the operation may proceed to operation 604.

At operation 606, a first risk score for the first data source and a second risk score of the second data source are obtained. The first risk score and the second risk score may be obtained by reading them from storage, obtaining them from another entity, generating them, and/or via other methods.

To generate the risk scores, information from a digital twin simulation that includes the first and/or second data source may be extracted. The information that is extracted may be based on a formula used to calculate the risk scores. The formula may use, as input, information regarding the likelihood of the respective data source malfunctioning (e.g., lack of power, failure of components of the data source, and/or any other factor that indicates that the data source is unlikely to operate in accordance with assumptions for its nominal operation), information regarding the likelihood of an environment impacting the respective data source in a manner that diverges from underlying assumptions (e.g., random debris landing on the data source), and/or other information that may be used as indicators of the propensity of the respective data source to provide accurate or inaccurate measurement data. Once obtained, the risk score for the respective data source may be stored for use.

The magnitude of the risk scores may be based on information obtained from multiple simulations with the digital twin model. For example, multiple simulations may be performed to take into account different potential states of the systems due to operation of stochastic elements (e.g., unpredictable elements such as system noise). Thus, the magnitudes for the risk scores may be based on information obtained from multiple runs of the digital twin model with different sets of values used as input to represent activity of the stochastic elements.

At operation 608, either the first value or the second value is selected as a trustworthy value. The selection may be based on the first risk score and the second risk score. The selection may be made by ranking the first data source and the second data source (e.g., rank order based on the risk scores). The value supplied by the highest ranked data source may be used as the trustworthy value.

As discussed above, the data sources may also be filtered (e.g., excluded from consideration) based on a variety of factors such as, for example, the manufacturer, an operator (e.g., the entity), duration of operation (e.g., minimum/maximum duration for the data source), etc. Thus, in some cases, a value supplied by a lower ranked data source may be selected if higher ranked data sources are excluded from consideration based on the filtering.

At operation 610, at least one potential future state of the data processing system is simulated using the digital twin model and the trustworthy value. The at least one potential future state may be simulated by using the trustworthy value as input for the digital twin model. The digital twin model may output the at least one potential future state based, at least in part, on the trustworthy value.

At operation 612, computer implemented services are provided using the data processing systems and the at least one potential future state. The computer implemented services may be provided by identifying, based at least in part on the at least one potential future state, a policy applicable to the data processing systems; updating, based on the policy, operation of the data processing systems to obtain updated data processing systems; and using the updated data processing systems to provide the computer implemented services. As discussed above, the policies may be keyed to statistics of multiple potential future states indicate by multiple simulations that predict the future state.

For example, multiple simulations may be performed using the digital twin model. In the different simulations, different sets of values for stochastic elements may be used. Thus, the different simulations may predict different potential outcomes based on different potential operation of the stochastic elements.

Refer to FIGS. 2A-4 for additional information regarding policies, application of policies, etc. to update the operation of data processing systems.

The method may end following operation 612.

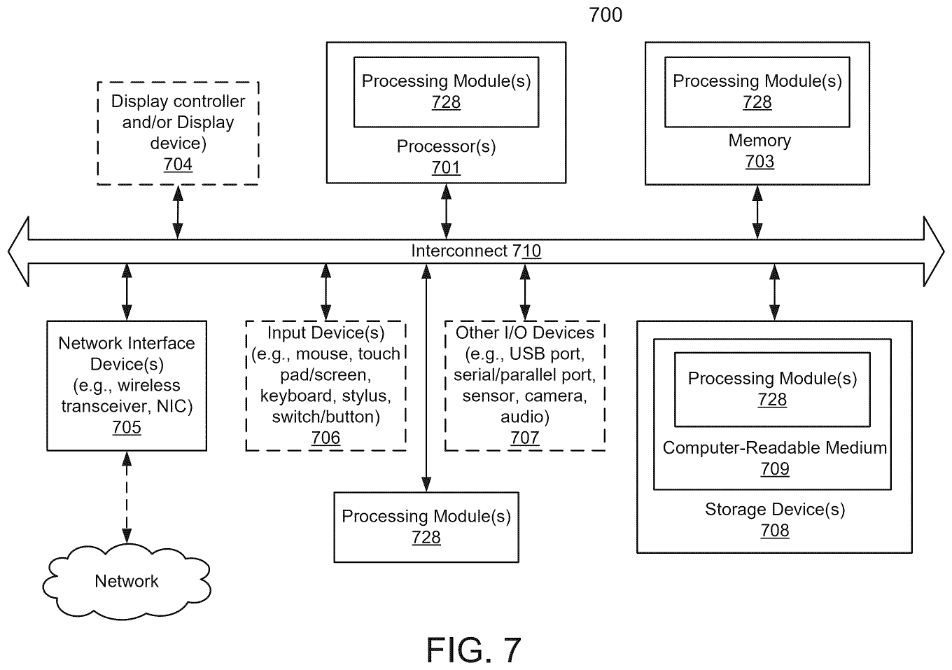

Any of the components illustrated in FIGS. 1-4 may be implemented with one or more computing devices. Turning to FIG. 7, a block diagram illustrating an example of a data processing system (e.g., a computing device) in accordance with an embodiment is shown. For example, system 700 may represent any of data processing systems described above performing any of the processes or methods described above. System 700 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 700 is intended to show a high level view of many components of the computer system. However, it is to be understood that additional components may be present in certain implementations and furthermore, different arrangement of the components shown may occur in other implementations. System 700 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 700 includes processor 701, memory 703, and devices 705-707 via a bus or an interconnect 710. Processor 701 may represent a single processor or multiple processors with a single processor core or multiple processor cores included therein. Processor 701 may represent one or more general-purpose processors such as a microprocessor, a central processing unit (CPU), or the like. More particularly, processor 701 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 701 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 701, which may be a low power multi-core processor socket such as an ultra-low voltage processor, may act as a main processing unit and central hub for communication with the various components of the system. Such processor can be implemented as a system on chip (SoC). Processor 701 is configured to execute instructions for performing the operations discussed herein. System 700 may further include a graphics interface that communicates with optional graphics subsystem 704, which may include a display controller, a graphics processor, and/or a display device.

Processor 701 may communicate with memory 703, which in one embodiment can be implemented via multiple memory devices to provide for a given amount of system memory. Memory 703 may include one or more volatile storage (or memory) devices such as random access memory (RAM), dynamic RAM (DRAM), synchronous DRAM (SDRAM), static RAM (SRAM), or other types of storage devices. Memory 703 may store information including sequences of instructions that are executed by processor 701, or any other device. For example, executable code and/or data of a variety of operating systems, device drivers, firmware (e.g., input output basic system or BIOS), and/or applications can be loaded in memory 703 and executed by processor 701. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 700 may further include IO devices such as devices (e.g., 705, 706, 707, 708) including network interface device(s) 705, optional input device(s) 706, and other optional IO device(s) 707. Network interface device(s) 705 may include a wireless transceiver and/or a network interface card (NIC). The wireless transceiver may be a WiFi transceiver, an infrared transceiver, a Bluetooth transceiver, a WiMax transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 706 may include a mouse, a touch pad, a touch sensitive screen (which may be integrated with a display device of optional graphics subsystem 704), a pointer device such as a stylus, and/or a keyboard (e.g., physical keyboard or a virtual keyboard displayed as part of a touch sensitive screen). For example, input device(s) 706 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 707 may include an audio device. An audio device may include a speaker and/or a microphone to facilitate voice-enabled functions, such as voice recognition, voice replication, digital recording, and/or telephony functions. Other IO devices 707 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 707 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 710 via a sensor hub (not shown), while other devices such as a keyboard or thermal sensor may be controlled by an embedded controller (not shown), dependent upon the specific configuration or design of system 700.

To provide for persistent storage of information such as data, applications, one or more operating systems and so forth, a mass storage (not shown) may also couple to processor 701. In various embodiments, to enable a thinner and lighter system design as well as to improve system responsiveness, this mass storage may be implemented via a solid state device (SSD). However, in other embodiments, the mass storage may primarily be implemented using a hard disk drive (HDD) with a smaller amount of SSD storage to act as a SSD cache to enable non-volatile storage of context state and other such information during power down events so that a fast power up can occur on re-initiation of system activities. Also a flash device may be coupled to processor 701, e.g., via a serial peripheral interface (SPI). This flash device may provide for non-volatile storage of system software, including a basic input/output software (BIOS) as well as other firmware of the system.

Storage device 708 may include computer-readable storage medium 709 (also known as a machine-readable storage medium or a computer-readable medium) on which is stored one or more sets of instructions or software (e.g., processing module, unit, and/or processing module/unit/logic 728) embodying any one or more of the methodologies or functions described herein. Processing module/unit/logic 728 may represent any of the components described above. Processing module/unit/logic 728 may also reside, completely or at least partially, within memory 703 and/or within processor 701 during execution thereof by system 700, memory 703 and processor 701 also constituting machine-accessible storage media. Processing module/unit/logic 728 may further be transmitted or received over a network via network interface device(s) 705.

Computer-readable storage medium 709 may also be used to store some software functionalities described above persistently. While computer-readable storage medium 709 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 728, components and other features described herein can be implemented as discrete hardware components or integrated in the functionality of hardware components such as ASICS, FPGAs, DSPs or similar devices. In addition, processing module/unit/logic 728 can be implemented as firmware or functional circuitry within hardware devices. Further, processing module/unit/logic 728 can be implemented in any combination hardware devices and software components.

Note that while system 700 is illustrated with various components of a data processing system, it is not intended to represent any particular architecture or manner of interconnecting the components; as such details are not germane to embodiments disclosed herein. It will also be appreciated that network computers, handheld computers, mobile phones, servers, and/or other data processing systems which have fewer components or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g. circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A method for managing data processing systems, the method comprising:
obtaining, from a first data source, first data indicating a first value for a quantity used in a digital twin model for the data processing systems;
obtaining, from a second data source, second data indicating a second value for the quantity used in the digital twin model for the data processing systems;
making an determination regarding whether a difference between the first value and the second value meet criteria;
in a first instance of the determination where the difference meets the criteria:
obtaining a first risk score for the first data source;
obtaining a second risk score for the second data source;
selecting, based on the first risk score and the second risk score, either the first value or the second value as a trustworthy value;
simulating, using the digital twin model and the trustworthy value, at least one potential future state of the data processing systems; and
providing computer implemented services using the data processing systems and the at least one potential future state.

2. The method of claim 1, wherein the first risk score is based on simulated operation of the first data source, and the second risk score is based on simulated operation of the second data source.

3. The method of claim 2, wherein a magnitude of the first risk score is based on, at least in part, a likelihood of malfunction of the first data source when the first data is obtained, the likelihood of malfunction being based on the simulated operation of the first data source.

4. The method of claim 3, wherein the magnitude of the first risk score is further based on, at least in part, an event predicted by simulated operation of other entities that impact the simulated operation of the first data source but that are not taking into account when the first data is obtained.

5. The method of claim 3, wherein the magnitude of the first risk score is further based on, at least in part, a second likelihood of malfunction of the first data source when the first data is obtained, the second likelihood of malfunction being based on a second simulated operation of the first data source.

6. The method of claim 5, wherein the second simulated operation of the first data source comprises a set of values selected to represent a stochastic element, the simulated operation of the first data source comprises a second set of values selected to represent the stochastic element, and the first set of values being different from the second set of values.

7. The method of claim 2, wherein the simulated operation of the first data source is simulated using the digital twin model.

8. The method of claim 1, wherein the first risk score is based on a function that ingests information obtained from at least one simulation of operation of the data processing systems using the digital twin model.

9. The method of claim 8, wherein the information comprises indicators of malfunction of the first data source.

10. The method of claim 1, wherein the first risk score and the second risk score reflect levels of trust in the first data source and the second data source operating in accordance with predefined expectations.

11. The method of claim 1, wherein the first data source is a first sensor, the second data source is a second sensor, and the first value and the second value are based on measurements, by the first sensor and the second sensor, respectively, that are consistent when the measurements are performed correctly.

12. The method of claim 1, wherein providing the computer implemented services comprises:
identifying, based at least in part on the at least one potential future state, a policy applicable to the data processing systems;
updating, based on the policy, operation of the data processing systems to obtain updated data processing systems; and
using the updated data processing systems to provide the computer implemented services.

13. A non-transitory machine-readable medium having instructions stored therein, which when executed by a processor, cause operations for managing data processing systems to be performed, the operations comprising:
obtaining, from a first data source, first data indicating a first value for a quantity used in a digital twin model for the data processing systems;
obtaining, from a second data source, second data indicating a second value for the quantity used in the digital twin model for the data processing systems;
making an determination regarding whether a difference between the first value and the second value meet criteria;
in a first instance of the determination where the difference meets the criteria:
obtaining a first risk score for the first data source;
obtaining a second risk score for the second data source;
selecting, based on the first risk score and the second risk score, either the first value or the second value as a trustworthy value;
simulating, using the digital twin model and the trustworthy value, at least one potential future state of the data processing systems; and
providing computer implemented services using the data processing systems and the at least one potential future state.

14. The non-transitory machine-readable medium of claim 13, wherein the first risk score is based on simulated operation of the first data source, and the second risk score is based on simulated operation of the second data source.

15. The non-transitory machine-readable medium of claim 14, wherein a magnitude of the first risk score is based on, at least in part, a likelihood of malfunction of the first data source when the first data is obtained, the likelihood of malfunction being based on the simulated operation of the first data source.

16. The non-transitory machine-readable medium of claim 15, wherein the magnitude of the first risk score is further based on, at least in part, an event predicted by simulated operation of other entities that impact the simulated operation of the first data source but that are not taking into account when the first data is obtained.

17. A system, comprising:
a processor; and
a memory coupled to the processor to store instructions, which when executed by the processor, cause operations for managing data processing systems to be performed, the operations comprising:
obtaining, from a first data source, first data indicating a first value for a quantity used in a digital twin model for the data processing systems;
obtaining, from a second data source, second data indicating a second value for the quantity used in the digital twin model for the data processing systems;
making an determination regarding whether a difference between the first value and the second value meet criteria;
in a first instance of the determination where the difference meets the criteria:
obtaining a first risk score for the first data source;
obtaining a second risk score for the second data source;
selecting, based on the first risk score and the second risk score, either the first value or the second value as a trustworthy value;
simulating, using the digital twin model and the trustworthy value, at least one potential future state of the data processing systems; and
providing computer implemented services using the data processing systems and the at least one potential future state.

18. The system of claim 17, wherein the first risk score is based on simulated operation of the first data source, and the second risk score is based on simulated operation of the second data source.

19. The system of claim 18, wherein a magnitude of the first risk score is based on, at least in part, a likelihood of malfunction of the first data source when the first data is obtained, the likelihood of malfunction being based on the simulated operation of the first data source.

20. The system of claim 19, wherein the magnitude of the first risk score is further based on, at least in part, an event predicted by simulated operation of other entities that impact the simulated operation of the first data source but that are not taking into account when the first data is obtained.
